(19) United States
(12) Patent Application Publication
(10) Pub. No.: US 2026/0282244 A1
(43) Pub. Date: Sep. 17, 2026

(54) ARTICULATING USER INTERFACE

(71) Applicants: BSH Home Appliances Corporation, Irvine, CA (US); BSH Hausgeräte GmbH, Munich (DE)

(72) Inventor: Suad Elkasevic, Winterville, NC (US)

(21) Appl. No.: 19/298,251

(22) Filed: Aug. 13, 2025

Related U.S. Application Data
(60) Provisional application No. 63/687,808, filed on Aug. 28, 2024.

(51) Int. Cl. H05K 5/00; F24C 7/08; H05K 5/02

(52) U.S. Cl. CPC H05K 5/0018; H05K 5/0226; F24C 7/086

(57) ABSTRACT

An articulating user interface for an appliance is disclosed. The user interface can be located along a front face of an appliance and may be articulated between a closed position that may be flush or substantially flush with the front of the appliance and an open position where the user interface projects from the front of the appliance and is oriented at a forward angle relative to the front of the appliance. The movement of the user interface may be motorized and the articulating movement of the user interface may be guided by cooperating hinge assemblies located at opposite ends of a user interface shell that carries various electronic components of the user interface. When in the articulated open position, a touchscreen front panel of the user interface may be presented to a user for inputting setting to or otherwise operating the appliance.

### CROSS-REFERENCE TO RELATED APPLICATIONS

This claims the benefit of U.S. Provisional Application 63/687,808, filed Aug. 28, 2024, titled ARTICULATING USER INTERFACE, the entirety of which is incorporated herein by reference.

### TECHNICAL FIELD

The present disclosure relates generally to household appliances and, more particularly (although not necessarily exclusively), to a user interface for a household appliance that is articulatable between a closed position and an open position.

### BACKGROUND

Home appliances such as, for example, cooking appliances may be equipped with a user interface (UI) that can be used to set operating parameters and control functions various functions of the appliance. For example, in the case of a cooking appliance embodied as a range or an oven, a UI may be provided and used to input settings such as the time and date and to set operating parameters such as heating, cooking, steaming, air frying, baking, broiling, or re-heating temperatures or times. In some appliance examples, a UI may be embedded in a flat panel that includes a touchscreen for manipulating controls and functions of the appliance. But such flat panel Uls are often embedded in an appliance at approximately waist level or otherwise below a countertop level, which can result in reduced visibility and usability of the UI. Furthermore, appliances such as ranges or ovens may have a bullnose that extends forward from a top thereof toward a user, with the resulting effect being that the UI may be not visible from eye level and can be obscured by the bullnose.

### SUMMARY

According to one example of the present disclosure, an articulating user interface for an appliance may include a user interface shell for housing a user interface, and a mounting frame having an opening. A first hinge assembly and a second hinge assembly may be arranged along opposite sides of the opening and configured to rotatably couple the user interface shell to a respective hinge case. The user interface shell can be configured to articulate from a position where a front panel of the user interface shell is substantially parallel with a front of the appliance to a position where at least the front panel of the user interface shell extends outwardly from the appliance by the first hinge assembly and the second hinge assembly causing the user interface shell to extend outwardly from the appliance.

According to another example of the present disclosure, a household appliance may include a cabinet including a front face and a user interface opening in the front face. An articulating user interface may be mounted in the cabinet and aligned with the user interface opening therein. The articulating user interface may comprise a user interface shell for housing a user interface, a mounting frame having an opening, and a first hinge assembly and a second hinge assembly arranged along opposite sides of the opening and configured to rotatably couple the user interface shell to a respective hinge case. The user interface shell can be configured to articulate from a position where a front panel of the user interface shell is substantially parallel with a front of the appliance to a position where at least the front panel of the user interface shell extends outwardly from the appliance by the first hinge assembly and the second hinge assembly causing the user interface shell to extend outwardly from the appliance.

According to another example of the present disclosure, a method may include receiving a command to articulate a user interface of an appliance. The method can also include, in response to receiving the command, causing a first hinge assembly and a second hinge assembly coupled to respective hinge cases and arranged along opposite sides of an opening in a mounting frame to rotate. The method can additionally include, in response to the first hinge assembly and the second hinge assembly rotating, articulating a user interface shell coupled to the first hinge assembly and the second hinge assembly from a position where a front panel of the user interface shell is substantially parallel with a front of the appliance to a position where at least the front panel of the user interface shell extends outwardly from the appliance.

### BRIEF DESCRIPTION OF THE DRAWINGS

FIG. 1A is a front view of an appliance with a motorized articulatable user interface shown in an open position according to one example of the present disclosure.

FIG. 1B is a side view of the appliance of FIG. 1A with the motorized articulatable user interface shown in the open position according to one example of the present disclosure.

FIG. 1C is an isometric view of a portion of the appliance of FIGS. 1A-1B with the motorized articulatable user interface shown in a closed position according to one example of the present disclosure.

FIG. 2 is a side view of a motorized articulatable user interface for an appliance according to one example of the present disclosure.

FIG. 3 is an isometric view of a rear portion of the motorized articulatable user interface of FIG. 2 according to one example of the present disclosure.

FIG. 4 is another isometric view of the rear portion of the motorized articulatable user interface of FIG. 2 according to one example of the present disclosure.

FIG. 5 is an enlarged cross-sectional isometric view of a motor and hinge assembly of the motorized articulatable user interface of FIG. 2 with the user interface in an open position according to one example of the present disclosure.

FIG. 6 is an enlarged cross-sectional isometric view of the motor and hinge assembly of FIG. 5 with the motorized articulatable user interface in a closed position according to one example of the present disclosure.

FIG. 7 is an isometric view of a rear portion of another motorized articulatable user interface according to another example of the present disclosure.

FIG. 8 is another isometric view of the rear portion of the motorized articulatable user interface of FIG. 7 according to another example of the present disclosure.

FIG. 9 is a side view of the motorized articulatable user interface of FIG. 7 according to one example of the present disclosure.

FIG. 10 is a rear view of the motorized articulatable user interface of FIG. 7 according to one example of the present disclosure.

FIG. 11 is a front view of the motorized articulatable user interface of FIG. 7 with a touchscreen panel thereof removed according to one example of the present disclosure.

FIG. 12 is an enlarged top view of a portion of the motorized articulatable user interface of FIG. 7 showing a hinge assembly coupled to a drive motor according to one example of the present disclosure.

FIG. 13 is a front view of the motorized articulatable user interface of FIG. 7 with a touchscreen panel thereof present according to one example of the present disclosure.

FIG. 14 is an enlarged isometric view of a hinge assembly of the motorized articulatable user interface of FIG. 7 according to one example of the present disclosure.

FIG. 15 is an enlarged side view of the hinge assembly of FIG. 14 according to another example of the present disclosure.

FIG. 16 is an isometric view of a rear portion of another motorized articulatable user interface according to one example of the present disclosure.

FIG. 17 is another isometric view of the rear portion of the motorized articulatable user interface of FIG. 16 according to one example of the present disclosure.

FIG. 18 is an isometric view of a front portion of the motorized articulatable user interface of FIG. 16 according to one example of the present disclosure.

FIG. 19 is an enlarged isometric view of a hinge assembly coupled to a drive motor of the motorized articulatable user interface of FIG. 16 according to one example of the present disclosure.

FIG. 20A is a cross-sectional side view of the motorized articulatable user interface of FIG. 16 shown in a closed position according to one example of the present disclosure.

FIG. 20B is a cross-sectional side view of the motorized articulatable user interface of FIG. 16 shown in a closed position according to one example of the present disclosure.

### DETAILED DESCRIPTION

Certain aspects and examples of the present disclosure relate to an articulating user interface (“user interface” or “UI”) that can be located along a front face of a household appliance, such as a cooking or cleaning appliance, and may be moved between a closed position that may be flush or substantially flush with the front of the appliance and an open position where the user interface projects from the front of the appliance at an advantageous user viewing and operating angle. Maintaining the user interface in the closed position when not in use may prevent the user interface from interfering with user movement along the front of the appliance and may, at least in some cases, also avoid soiling of the user interface during use of the appliance.

The movement of the user interface between the closed position and the open position may be a motorized movement. For example, upon receiving a signal, a drive motor associated with the user interface can be activated to cause at least a touchscreen portion of the user interface to rotate from the closed position to the open position or to return from the open position to the closed position. A drive motor(s) may operate in cooperation with a hinge assembly to produce a desired opening and closing movement of the user interface. The movement of the user interface may be an articulating movement, such that a touchscreen or other user facing portion of the user interface not only rotates but moves outward (forward) relative to the front face of the appliance. Such an articulating movement may place the user interface in a more advantageous user viewing position than can be produced by a purely rotational movement—for example, if the user interface is located below a protruding bullnose or other protruding feature of the front portion of the appliance.

In some examples, a motorized opening or closing movement of the user interface can be triggered by a signal generated by a user of the appliance. For example, a sensor may detect pressure exerted on a touchscreen (e.g., glass panel) of the user interface by the finger of a user, the user may press a button on the touchscreen, the user may select an “open” or “close” option from a menu viewable on the touchscreen, etc. In another example, a user interface opening or closing signal can be generated by a proximity sensor that is associated with the appliance in response to detecting or not detecting the presence of a user. For example, if the user interface is in the open position and the proximity sensor does not detect the presence of a user for some period of time, a signal may be generated to cause the drive motor(s) to move the user interface to the closed position. A signal usable to trigger a motorized movement of the user interface from a closed position to an open position, or vice versa, may also be generated upon turning on the appliance (in person or remotely).

In some examples, a user may prohibit (until reset) opening of the user interface. In some examples, a user may set/program an open position of the user interface that is less than a fully open position—i.e., a position that is somewhere between the open and closed positions. Likewise, in some examples, a user may set/program a closed position of the user interface that is less than a fully open position—i.e., a position that is not completely flush with a front of the appliance.

In some examples, a user interface may include a mounting frame for connecting and supporting various components of the user interface. The mounting frame may also be used to mount the user interface to an appliance (e.g., to an appliance cabinet). The mounting frame may have an opening, which may be bounded by an upper frame member and first and second side frame members in some examples.

A user interface according to examples of the present disclosure may include a first and second hinge assembly. The first and second hinge assemblies may be disposed along opposite ends of the mounting frame. In some examples, the hinge assemblies may employ a four-pivot point design. For example, each hinge assembly may include a hinge case, an inner linkage arm rotatably coupled at a first end to an inner face of the hinge case and at a second end to the upper frame member of the mounting frame, and an outer linkage arm rotatably coupled at a first end to an outer face at a different location of the hinge case and at a second end to a different location on the upper frame member of the mounting frame.

The hinge assemblies may be affixed by their respective hinge cases to opposite ends of a user interface shell such that the user interface shell is arranged below the upper frame member and aligned with the opening in the mounting frame. The user interface shell may be a substantially hollow component so as to receive and retain various electronic components of the user interface, including a forward-facing touchscreen and a user interface glass sheet (cover plate) thereof. The hinge assemblies ensure an articulating motion upon driven movement of the user interface shell, as described in more detail below.

A drive motor such as an electric (e.g., gear) motor may be coupled to the user interface shell via one or both hinge assemblies. For example, the drive motor may be mounted to a side frame of the mounting frame with an output shaft of the drive motor coupled to the hinge case of the associated hinge assembly. Additional drive assembly components such as a cam plate and a connecting shaft may be used to couple the drive motor to the hinge case. As a result of such a drive motor coupling, the user interface shell is articulatable through the opening in the mounting frame by a rotation of the drive motor output shaft, and between a closed and open position.

In some examples, the drive motor may be located outside the inside boundary (i.e., outside of the interior volume) of the user interface shell. In other examples, the drive motor may be located within the inside boundary (i.e., within the interior volume) of the user interface shell. In some examples, two drive motors may be used, with a drive motor coupled to each hinge assembly of the pair of hinge assemblies.

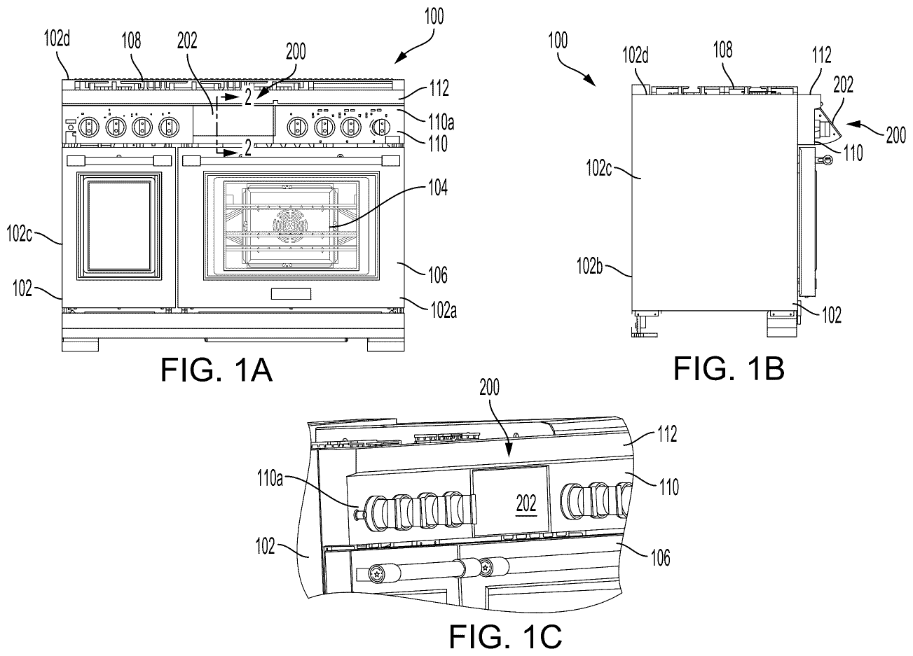

FIGS. 1A-1C depict a cooking appliance in the form of a range 100, but appliances according to the present disclosure are not limited to cooking appliances. For example, an appliance with which a user interface according to the present disclosure can be used may instead be a cleaning appliance, such as a clothes-washing or clothes-drying appliance, or a dishwashing appliance. An application of a user interface of the present disclosure to other appliance types is also possible.

In the example of FIGS. 1A-1C, the range 100 is equipped with a motorized articulatable user interface 200 (“user interface” or “UI”) according to one example of the present disclosure. As used herein, “range” is intended to denote a cooking appliance that includes both an enclosed heating space where food can be baked, broiled, steamed, etc., and a cooktop or stovetop where food may be grilled, fried, seared, boiled, etc., using heat generated by for example, natural gas or propane burners, or electric resistance or magnetic inductance coils. As used herein, “oven” is intended to denote a cooking appliance that includes an enclosed heating space where food can be baked, broiled, steamed, etc. In some examples, an oven may be a freestanding appliance. In other examples, an oven may be installed to an opening in a wall or a cabinet or to a cooktop or stovetop that is mounted in or on a countertop or cabinet and lacks an oven portion.

The range 100 depicted in FIGS. 1A-1C includes a cabinet 102 having a front face 102a a rear face 102b, opposed sides 102c, and a top 102d. An oven 104 is located within the cabinet 102 and is accessible via a hinged door 106 that can open and close along the front face 102a of the cabinet 102. The oven 104 may be any type of oven, including without limitation, a conventional oven, a convection oven, a steam oven, or a combination oven with combined cooking capabilities, which may include microwave cooking functionality in some instances. Heat for the oven may be generated using gas or electricity. In some examples, more than one oven may be present. The range 100 also includes a stovetop/cooktop 108. The stovetop/cooktop 108 may include any number and combination of burners, grilling grates, griddles, or other cooking elements for which cooking heat is generated using gas or electricity.

The range 100 includes a front panel assembly 110 in which is mounted the user interface 200. In this example, the front panel assembly 110 also includes a forward-protruding bullnose 112 that is visible at a location above the user interface 200. The articulating movement of the user interface 200 can place the user interface 200 in an operative position where visibility of and access to the user interface 200 is not impeded by the bullnose 112.

In the front view of FIG. 1A and the side view of FIG. 1B, the user interface 200 is shown in an open (use) position where a touchscreen 202 resides forward of and is pivoted upward relative to a front face 110a of the front panel assembly 110 of the range 100. Such an open position of the user interface 200 can optimize the visibility of the touchscreen 202 to a user standing in front of the range 100 and can also place the touchscreen 202 in a position that is ergonomically friendly to user interaction. As illustrated, the articulating motion of the user interface 200 can render the touchscreen 202 highly visible to and easily usable by a user despite the presence of the overhanging bullnose 112. While the user interface 200 is designed to be operated by a user in the open position, the user interface 200 may also be operated by a user in the closed position (see FIG. 1C) or at some articulated position between the open position and the closed position according to some examples.

In the isometric partial view of the range 100 depicted in FIG. 1C, the user interface 200 has been articulated from the open position of FIGS. 1A-1B to a closed position where the touchscreen 202 (or another user-interactive front panel) of the user interface 200 may be flush with or substantially flush with the front face 110a of the front panel assembly 110. In other examples where a range or oven lacks such a front panel assembly, the user interface 200 may be mounted directly in the cabinet 102 and the touchscreen 202 of the user interface 200 may be flush with or substantially flush with the front face 102a of the cabinet 102 when in the closed position. Such a flush or substantially flush closed position of the user interface 200 can prevent the user interface 200 from being damaged (e.g., by inadvertent user contact) or soiled when not in use.

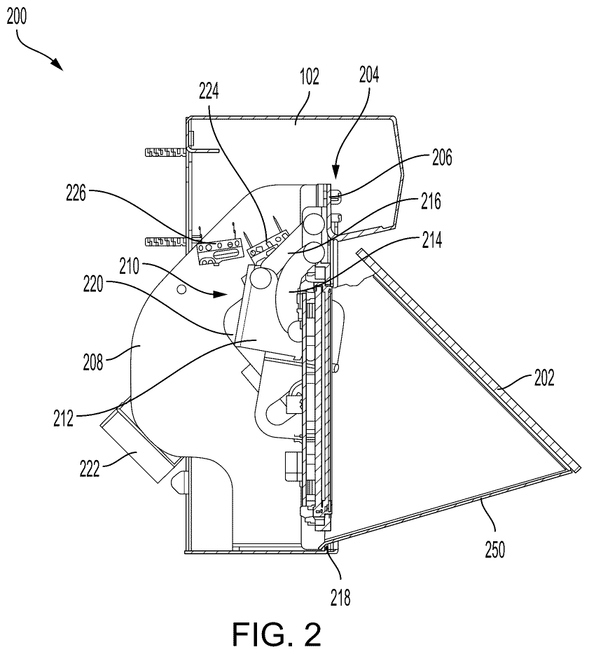

FIGS. 2-6 illustrate additional details of the user interface 200 example of FIGS. 1A-1C. FIG. 2 is a cross-sectional side view of the open position user interface 200 taken along line 2-2 of FIG. 1A. The user interface 200 can be observed to have a mounting frame 204, of which an upper frame member 206 and a first side frame member 208 (of two side frame members) are visible in FIG. 2. The first side frame member 208 is arranged at a first end of the upper frame member 206 and extends transversely and rearwardly therefrom.

The user interface 200 can also be seen to include a first hinge assembly 210 (of two hinge assemblies) used to mount a user interface shell 250 to the mounting frame 204 in an articulatable manner. The first hinge assembly 210 includes a first hinge case 212. In this example, a first inner linkage arm 214 of the first hinge assembly 210 is rotatably coupled at a first end to an inner face of the first hinge case 212 and at a second end to the upper frame member 206, and a first outer linkage arm 216 arm of the first hinge assembly 210 is rotatably coupled at a first end to an outer face of the first hinge case 212 and at a second end to the upper frame member 206. Rotatable pins or other connecting elements that enable rotation of the first hinge case 212 and the first inner and outer linkage arms 214, 216 may be used to couple the first inner and outer linkage arms 214, 216 to the first hinge case 212 and to the upper frame member 206. The first hinge assembly 210 facilitates an articulating movement of the user interface shell 250 from the closed position of FIG. 1C to the open position of FIGS. 1A-1B through an opening 218 in the mounting frame 204. FIG. 2 also depicts a portion of a cam plate 220 used to couple a drive motor to the first hinge case 212 and a portion of a drive motor electrical connector 222. A pair of limit (e.g., microswitches) 224, 226 are also present and are used to respectively detect the open position and the closed position of the user interface 200. Other types of sensors may be used to detect user interface position in other examples.

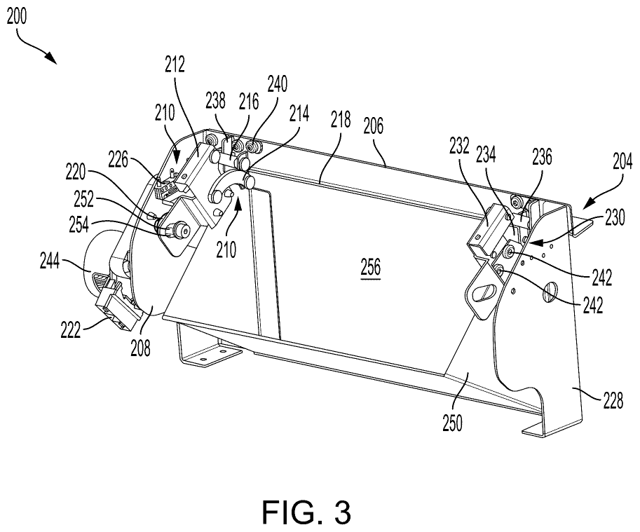

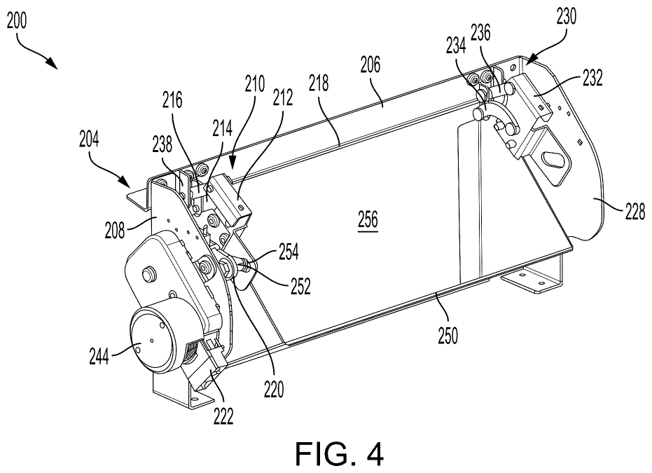

FIG. 3 and FIG. 4 are isometric views of a rear portion of the motorized articulatable user interface 200 with the user interface shell 250 in a closed position according to one example of the present disclosure. As shown, the mounting frame 204 further includes a second side frame member 228 that is arranged at an opposite end of the upper frame member 206 from the first side frame member 208 and also extends transversely and rearwardly from the upper frame member 206. The upper frame member 206 and the first and second side frame members 208, 228 thus bound the opening 218 in the mounting frame 204.

A second hinge assembly 230 is also visible in FIGS. 3-4. The second hinge assembly 230 cooperates with the first hinge assembly 210 to mount the user interface shell 250 to the mounting frame 204 in an articulatable manner. The second hinge assembly 230, like the first hinge assembly 210, includes a second hinge case 232, a second inner linkage arm 234 that is rotatably coupled at a first end to an inner face of the second hinge case 232 and at a second end to the upper frame member 206, and a second outer linkage 236 that is rotatably coupled at a first end to an outer face of the second hinge case 232 and at a second end to the upper frame member 206. The second ends of the first inner linkage arm 214 and the first outer linkage arm 216 of the first hinge assembly 210 and the second ends of the second inner linkage arm 234 and the second outer linkage 236 of the second hinge assembly can be affixed to the upper frame member 206 in a number of ways including, for example, by way of brackets 238 and associated threaded fasteners 240. Likewise, the user interface shell 250 may be secured to the hinge cases 212, 232 of the respective first hinge assembly 210 and second hinge assembly 230 in a number of ways including, for example, by way of threaded fasteners 242.

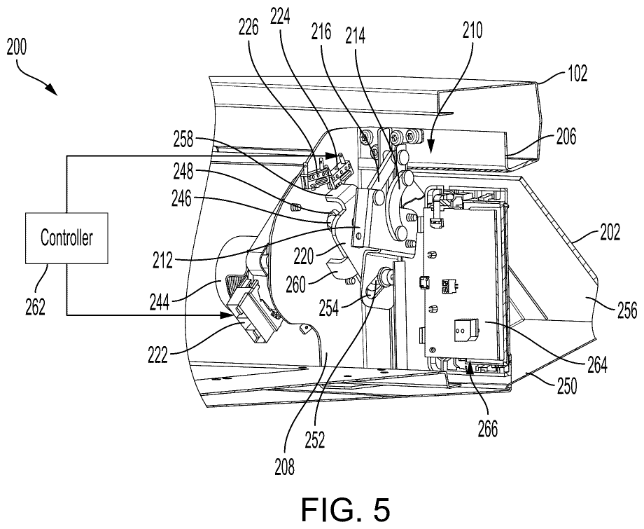

The user interface shell 250 may be articulatable through the opening 218 in the mounting frame 204 and between an open position and a closed position by an electric drive motor 244. In at least some examples, the electric drive motor 244 may be a gear motor. In this example of the user interface 200, the electric drive motor 244 is mounted to an outer face of the of the first side frame member 208 to be located outside of the user interface shell 250. The electric drive motor 244 can include a drive shaft 246 that extends inwardly toward the user interface shell 250 and through an aperture 248 in the first side frame member 208 (see FIG. 5). In other examples, the electric drive motor 244 may instead be affixed to the second side frame member 228, or two electric drive motors 244 can be cooperatively used to articulate the user interface shell 250, in which case an electric drive motor 244 can be affixed to each of the first side frame member 208 and the second side frame member 228.

To articulate the user interface shell 250, the drive shaft 246 of the electric drive motor 244 can be coupled to the first hinge case 212 of the first hinge assembly 210. In this example, a cam plate 220 is interposed between and used to couple the drive shaft 246 of the electric drive motor 244 to the first hinge case 212. More specifically, the cam plate 220 may be coupled near a first end thereof to the drive shaft 246 of the electric drive motor 244 such that the cam plate 220 is rotated by the drive shaft 246 during operation of the electric drive motor 244. The cam plate 220 may also be coupled near a send end thereof to a connecting shaft 252 or a similar element that is usable to connect the cam plate 220, and this the drive shaft 246 of the electric drive motor 244 to the first hinge case 212. For example, the connecting shaft 252 may extend through a slot 254 in the first hinge case 212. In this manner, selective operation of the electric drive motor 244 in conjunction with connection of the user interface shell 250 to the hinge assemblies 210, 230 will produce an articulating movement of the user interface shell 250 through the opening 218 in the mounting frame 204 and between the open and closed positions. In some examples, the connecting shaft 252 may be comprised of a low friction material (e.g., nylon) or may include a rotatable bearing to facilitate displacement of the connecting shaft 252 within the slot 254 in the first hinge case 212.

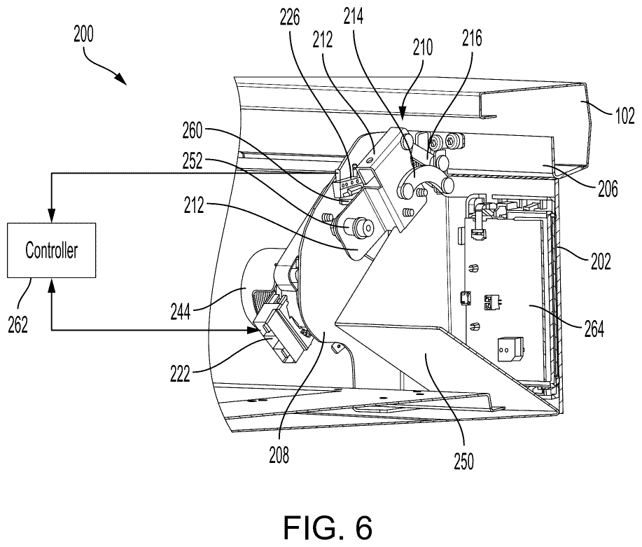

As is observable in FIGS. 3-4, the user interface shell 250 is substantially hollow to accommodate various electronic components of the user interface 200 (see FIGS. 5-6). These electronic components have been omitted from the interior space of the user interface shell 250 in FIGS. 3-4 for purposes of clarity. It may also be observed that a sheet of user interface glass 256 or a similar protective material may serve as the outermost (forwardmost) component of the touchscreen 202 or another user-interactive portion of the user interface 200.

FIG. 5 is an enlarged cross-sectional rear isometric view of the electric drive motor 244 and first hinge assembly 210 of the user interface 200 of FIG. 2 with the user interface in an open position according to one example of the present disclosure. In FIG. 5, the open user interface positions of, for example, the user interface shell 250, the touchscreen 202 and associated user interface glass 256, the first hinge case 212, the first inner linkage arm 214, the first outer linkage arm 216, the cam plate 220, and the connecting shaft 252, may be observed. It may be further observed that the cam plate 220 may include an open position indicating tab 258 and a closed position indicating tab 260. The open position indicating tab 258 may be usable to indicate to a controller 262 (e.g., drive motor controller) or a similar device that the user interface shell 250 is in the open position. For example, the open position indicating tab 258 may be detected by the first (open position) microswitch 224 when the user interface shell 250 is in the open position, and the open position microswitch 224 may resultantly send a signal indicating the same to the controller 262. FIG. 5 also illustrates that electronic components such as but not limited to a printed circuit board 264 may be located within the interior space of the user interface shell 250. Other components, layers, substrates 266, etc., related to the operation of the user interface 200 may also be present in the user interface shell 250.

FIG. 6 is an enlarged cross-sectional rear isometric view of the electric drive motor 244 and first hinge assembly 210 of the user interface 200 of FIG. 2 with the user interface in a closed position according to one example of the present disclosure. In FIG. 6, the closed user interface positions of, for example, the user interface shell 250, the touchscreen 202, the first hinge case 212, the first inner linkage arm 214, the first outer linkage arm 216, and the connecting shaft 252, may be observed. The position of the cam plate 220 closed position indicating tab 260 can also be observed. The closed position indicating tab 260 may be usable to indicate to the controller 262 or a similar device that the user interface shell 250 is in the closed position. For example, the closed position indicating tab 260 may be detected by the second (closed position) microswitch 226 when the user interface shell 250 is in the closed position, and the closed position microswitch 226 may resultantly send a signal indicating the same to the controller 262.

As can be understood from FIGS. 5-6, the first inner linkage arm 214 and the first outer linkage arm 216 are rotatably connected at different locations on the hinge case 212 and at different locations on the upper frame member 206 (e.g., on the bracket 238) such that the first hinge assembly 210 has a four-pivot point design. The second hinge assembly 230 may also have a four-pivot point design. The four-pivot point design of the hinge assemblies 210, 230 enables the hinge assemblies 210, 230 to cooperatively direct the movement of the user interface shell 250 along a simultaneously rotational and translational path during articulation thereof. Thus, the in the open position, the user interface shell 250 can be both translated forward and angled forward relative to the front of the mounting frame 204 or the front of an appliance cabinet (e.g., cabinet 102). In some examples, a front face of a front panel of the user interface shell 250 may be translated approximately 20 millimeters forward of the front of the mounting frame 204 or the front of an appliance cabinet while the viewing angle of the user interface touchscreen 202 can be simultaneously changed from a home (closed) position of 0° or approximately 0° to an angle of up to approximately 45° when fully open. Other touchscreen 202 translation distances and viewing angles may also be possible. Additionally, the user interface 200 may allow a user to select open angles between the ranges of approximately 1° to 45°. As previously described, such an articulating movement of the user interface shell 250 can place the touchscreen 202 of the user interface 200 in an optimized viewing and use position.

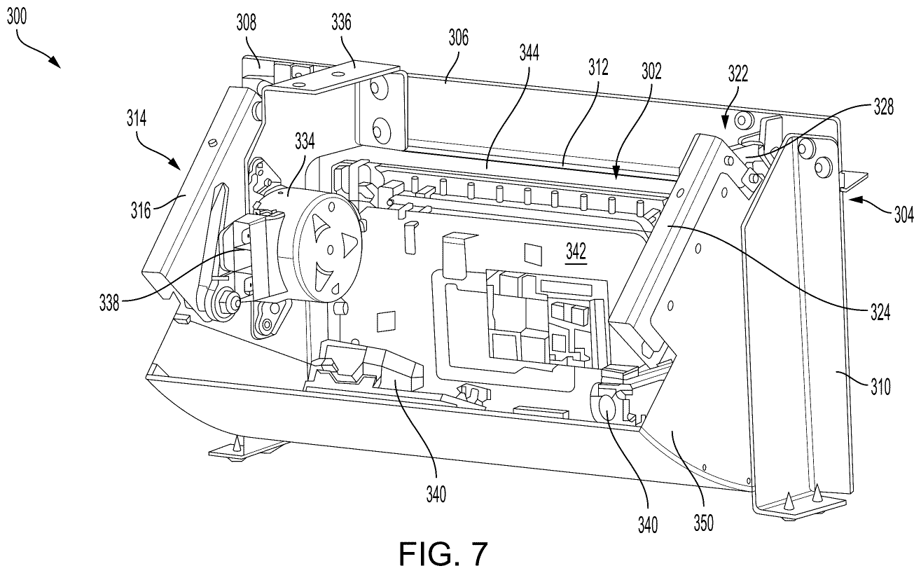

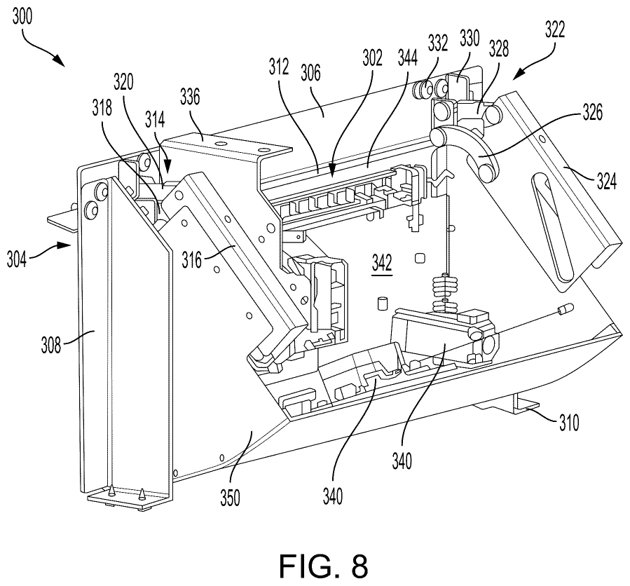

FIGS. 7-15 illustrate another motorized articulatable user interface (“user interface” or “UI”) 300 according to another example of the present disclosure. FIG. 7 and FIG. 8 are isometric views of a rear portion of the user interface 300 in a closed position and including a forward-facing (user-facing) touchscreen 302. As shown, the user interface 300 includes a mounting frame 304 having an upper frame member 306, a first side frame member 308 that extends transversely and rearwardly from the upper frame member 306, and a second side frame member 310 that also extends transversely and rearwardly from the upper frame member 306. The first side frame member 308 and the second side frame member 310 are arranged at opposite ends of the upper frame member 306 such that the upper frame member 306 and the first and second side frame members 308, 310 bound an opening 312 in the mounting frame 304.

The user interface 300 can also include a first hinge assembly 314 and a second hinge assembly 322 that cooperate to mount a user interface shell 350 to the mounting frame 304 in an articulatable manner. In this example, the first hinge assembly 314 includes a first hinge case 316, a first inner linkage arm 318 that is rotatably coupled at a first end to an inner face of the first hinge case 316 and at a second end to the upper frame member 306, and a first outer linkage arm 320 that is rotatably coupled at a first end to an outer face of the first hinge case 316 and at a second end to the upper frame member 306. Similarly, the second hinge assembly 322 includes a second hinge case 324, a second inner linkage arm 326 that is rotatably coupled at a first end to an inner face of the second hinge case 324 and at a second end to the upper frame member 306, and a second outer linkage arm 328 that is rotatably coupled at a first end to an outer face of the second hinge case 324 and at a second end to the upper frame member 306. The first and second hinge assemblies 314, 322 cooperatively facilitate an articulating movement of the user interface shell 350 from the closed position shown in FIGS. 7-8 to an open position like or similar to the open position of the user interface 200 depicted in FIGS. 1A-1B. Movement of the user interface shell 350 from the closed position to the open position will cause at least a portion of the user interface shell 350 to pass through the opening 312 in the mounting frame 304.

The second ends of the first inner linkage arm 318 and the first outer linkage arm 320 of the first hinge assembly 314, and the second ends of the second inner linkage arm 326 and the second outer linkage arm 328 of the second hinge assembly 322, can be affixed to the upper frame member 306 in a number of ways including, for example, by way of brackets 330 and associated threaded fasteners 332. Likewise, the user interface shell 350 may be secured to the hinge cases 316, 324 of the respective first hinge assembly 314 and second hinge assembly 322 in a number of ways including, for example, by way of threaded fasteners. Rotatable pins or other connecting elements that enable rotation of the hinge cases 316, 324 and the linkage arms 318, 320, 326, 328 may be used to couple the linkage arms 318, 320, 326, 328 to the respective hinge cases 316, 324 and to the upper frame member 306.

FIGS. 7-8 also depict the use of an electric drive motor 334 and associated drive assembly members for articulating the user interface shell 350 through the opening 312 in the mounting frame 304 and between an open position and a closed position. In at least some examples, the electric drive motor 334 may be a gear motor. In this example of the user interface 300, the electric drive motor 334 is located within an interior volume of the user interface shell 350 and secured to a motor mount 336 that may be affixed to the upper frame member 306 of the mounting frame 304. The drive motor may include a connector 338 by which electrical energy and control signals can be provided to the electric drive motor 334.

As is observable in FIGS. 7-8, the user interface shell 350 is substantially hollow to accommodate various electronic components 340 of the user interface 300. A printed circuit 342 board may also reside within the interior volume of the user interface shell 350. It may also be observed that a sheet of user interface glass sheet 344 or a similar protective material may serve as the outermost (forwardmost) component of the touchscreen 302 or another user-interactive portion of the user interface 300. An overall interactive (e.g., touchscreen) user interface may be enabled by the various electronic components located in the interior space of the user interface shell 350.

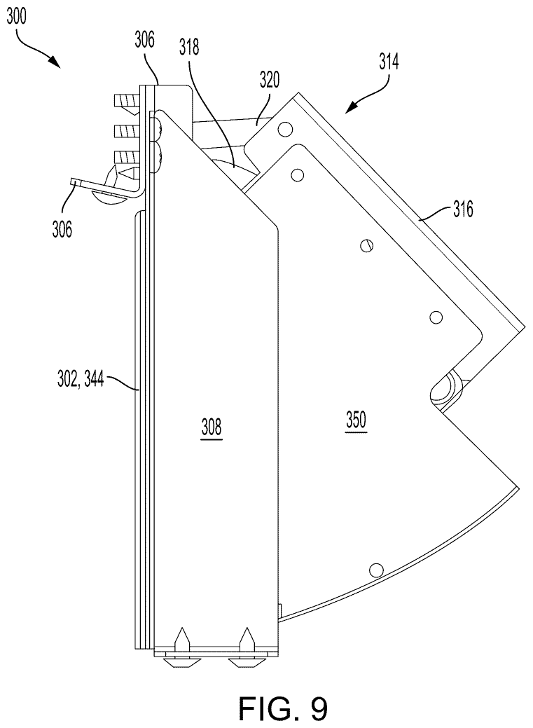

FIG. 9 is a side view of the user interface 300 where the user interface shell 350 may be observed in the closed (retracted) position. In the closed position, the touchscreen 302 (e.g., a forwardmost user interface glass sheet 344) may be flush or substantially flush with the mounting frame 304 or with a front face of an appliance cabinet (e.g., cabinet 102 of FIGS. 1A-1C) to which the user interface 300 is installed. The positions of the first hinge case 316, the first inner linkage arm 318, and the first outer linkage arm 320 of the first hinge assembly 314, are also shown in FIG. 9 in their closed positions.

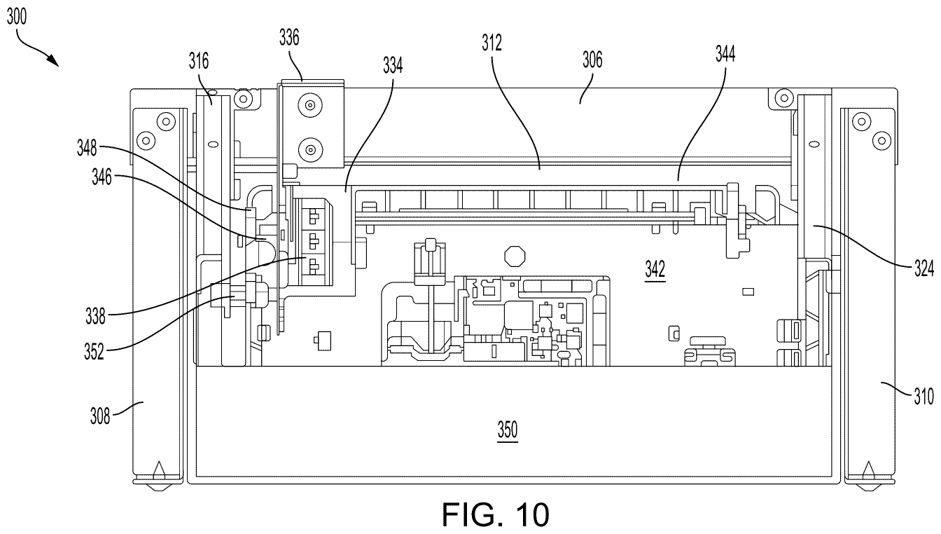

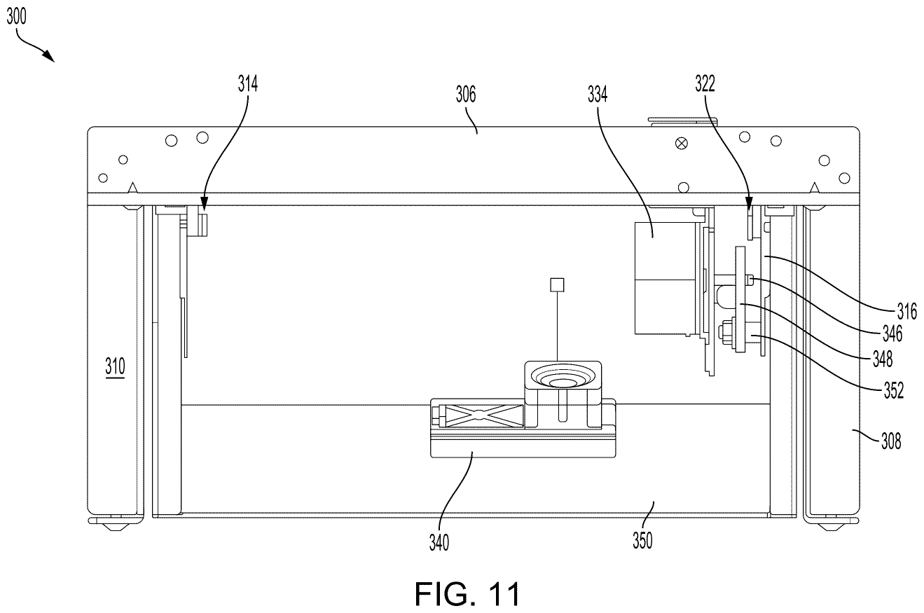

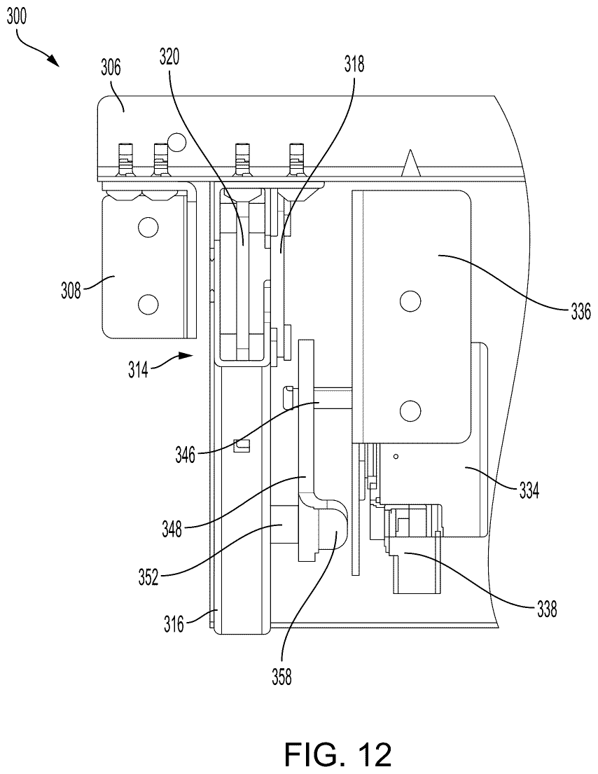

FIGS. 10-12 illustrate how motorized articulation of the user interface shell 350 may be accomplished according to one example of the user interface 300. FIG. 10 is a rear view of the user interface 300. FIG. 11 is a front view of the user interface 300 with the touchscreen 302 thereof removed. FIG. 12 is an enlarged top view of a portion of the user interface 300 showing the first hinge case 316 coupled to the electric drive motor 334. It may be observed in FIGS. 10-12 that the electric drive motor 334 can include a drive shaft 346 that extends outwardly toward the first hinge assembly 314. In another example, the electric drive motor 334 may instead be affixed to a motor mount 336 near the opposite end of the user interface shell 350 and the drive shaft 346 may extend toward the second hinge assembly 322. In still another example, two electric drive motors 334 can be cooperatively used to articulate the user interface shell 350, in which case an electric drive motor 334 can be affixed to respective motor mounts near opposite ends of the user interface shell 350.

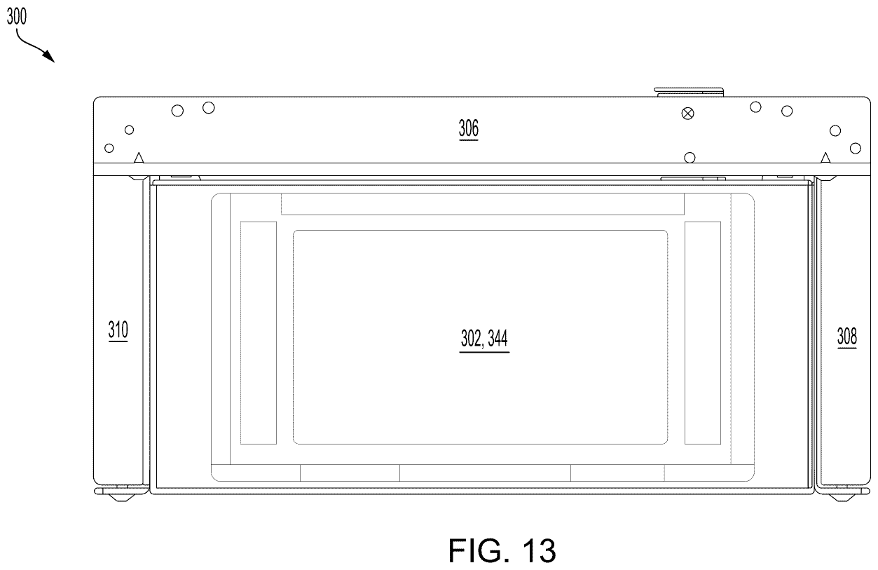

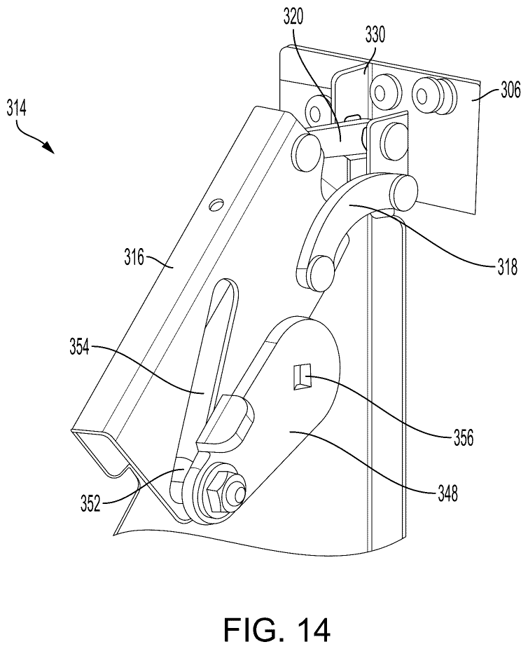

To articulate the user interface shell 350, the drive shaft 346 of the electric drive motor 334 can be coupled to the first hinge case 316 of the first hinge assembly 314. In this example, a cam plate 348 is interposed between and used to couple the drive shaft 346 of the electric drive motor 334 to the first hinge case 316. More specifically, the cam plate 348 may be coupled near a first end thereof to the drive shaft 346 of the electric drive motor 334 such that the cam plate 348 is rotated by the drive shaft 346 during operation of the electric drive motor 334. The cam plate 348 may also be coupled near a second end thereof to a connecting shaft 352 or a similar element that is usable to connect the cam plate 348, and thus the drive shaft 346 of the electric drive motor 334, to the first hinge case 316. For example, the connecting shaft 352 may extend through a slot 354 (see FIGS. 13-14) in the first hinge case 316. In this manner, selective operation of the electric drive motor 334 in conjunction with connection of the user interface shell 350 to the hinge assemblies 314, 322 will produce an articulating movement of the user interface shell 350 through the opening 312 in the mounting frame 304 and between the open and closed positions. In some examples, the connecting shaft 352 may be comprised of a low friction material (e.g., nylon) or may include a rotatable bearing to facilitate movement of the connecting shaft 352 within the slot 354 in the first hinge case 316.

FIG. 13 is a front view of the user interface 300 with the touchscreen 302 thereof present and the user interface shell 350 in a closed position according to one example of the present disclosure. It may be observed in FIG. 12 that the user interface glass sheet 344 (or other forwardmost cover) of the touchscreen 302 is aligned within the opening 312 in the mounting frame 304. Additionally, FIG. 12 represents how the user interface glass sheet 344 or other forwardmost cover of the touchscreen 302 may be flush or substantially flush with the front face of the mounting frame 304 or a front face of a cabinet in which the user interface 300 is installed when the user interface shell 350 is in the closed position.

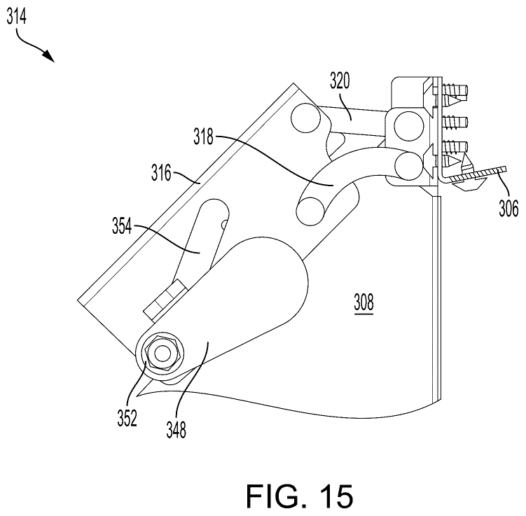

FIG. 14 is an enlarged isometric view and FIG. 15 is an enlarged side view of the first hinge assembly 314 of the user interface 300 according to one example of the present disclosure. In FIGS. 14-15, the rotatable connection of the first hinge case 316 to the first inner linkage arm 318 and to the first outer linkage arm 320 is shown in more detail, as is the rotatable connection of the first inner linkage arm 318 and the first outer linkage arm 320 to the upper frame member 306 of the mounting frame.

The positioning of the cam plate 348 relative to the first hinge case 316 and the slot 354 in the first hinge case 316 that receives the connecting shaft 352 coupled to the cam plate 348 are also shown in greater detail in FIGS. 14-15. A drive shaft receiving aperture 356 is also visible in the cam plate 348 for coupling the cam plate 348 to the electric drive motor 334. The cam plate 348 may also include a position indicating tab(s) 358 or a similar feature(s) that can cooperate with sensors such as the microswitches 224, 226 described above to determine and report a position of the user interface shell 350 to a controller.

As can be better understood from FIGS. 14-15, the four-pivot point design of the first hinge assembly 314 (and the second hinge assembly 322) is such that the user interface shell 350 can be articulated through the opening 312 in the mounting frame to a position that is both pivoted (angled) and linearly forward of the front face of the mounting frame 304 upon an appropriately directed rotational operation of the electric drive motor 334. For example, as a result of the articulating movement thereof, the user interface shell 350 may be translated forward and angled forward relative to the front of the mounting frame 304 or the front of an appliance cabinet (e.g., cabinet 102). In some examples, a front face of a front panel of the user interface shell 350 may be translated approximately 20 millimeters forward of the front of the mounting frame 304 or the front of an appliance cabinet while the viewing angle of the user interface touchscreen 302 can be simultaneously changed from a home (closed) position of 0° or approximately 0° to an angle of up to approximately 45° when fully open. Other translation distances and viewing angles of the open touchscreen 302 may also be possible. Additionally, the user interface 300 may allow a user to select open angles between the ranges of 1° to 45°. As previously described, such an articulating movement of the user interface shell 350 can place the touchscreen 302 of the user interface 300 in an optimized viewing and use position.

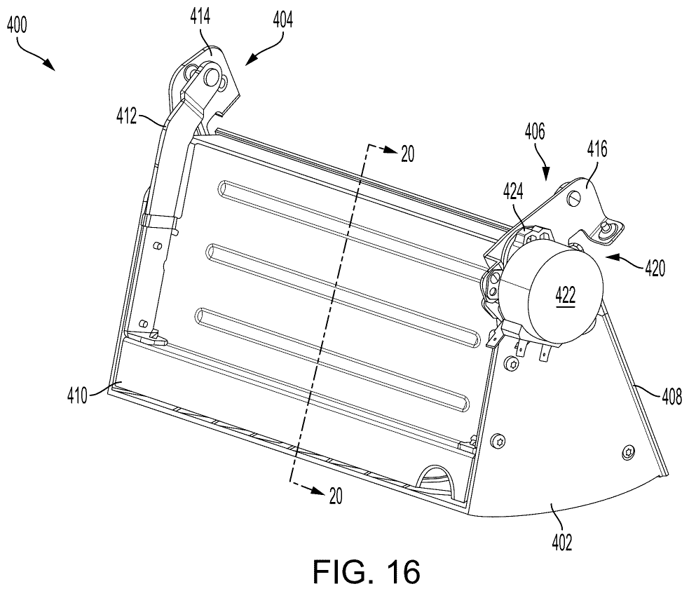

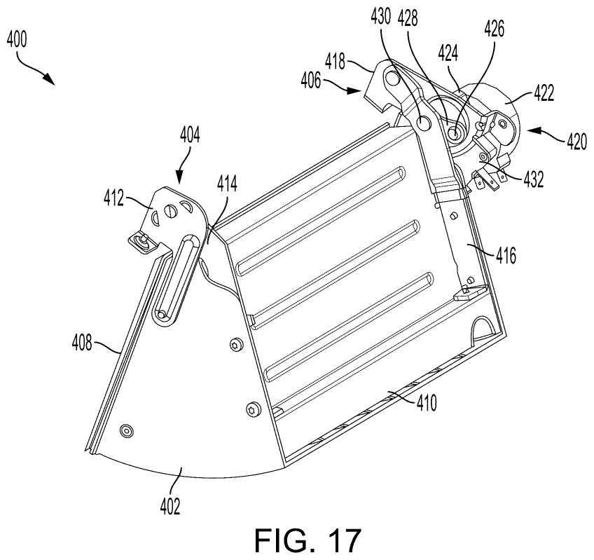

FIGS. 16-20 illustrate another motorized articulatable user interface (“user interface” or “UI”) 400 according to one example of the present disclosure. FIGS. 16-17 are isometric views of a rear portion of the user interface 400. This example of the user interface 400 includes a user interface shell 402 and a cooperating pair of hinge assemblies 404, 406 that can be used to direct the user interface shell 402 through an opening and closing articulated movement relative to an appliance, as described above. The user interface 400 can also have a front panel that is located along a front face of the user interface shell 402 and may include a touchscreen via which a user can interact with and operate the user interface 400 and an appliance to which the user interface 400 is installed. The touchscreen may be covered by a user interface glass 408 or a similar sheet in some examples. In this example, the user interface shell 402 of the user interface 400 also includes a rear panel 410 that nay function as an electrical cover and may also reinforce the covered by a user interface shell 402.

The first hinge assembly 404 of the pair of hinge assemblies 404, 406 includes a first inner linkage arm 412 that is affixed to an inner face of the user interface shell 402 along one side of thereof. The first hinge assembly 404 also includes a first outer linkage arm 414 that is rotatably coupled to the first inner linkage arm 412, affixed to an outer face of the user interface shell 402, and is further configured to secure the user interface 400 to a mounting frame or to a component (e.g., front panel) of an appliance. The second hinge assembly 406 of the pair of hinge assemblies 404, 406 also includes a second inner linkage arm 416 that is affixed to an inner face of the user interface shell 402 along an opposite side thereof, and a second outer linkage arm 418 that is rotatably coupled to the second inner linkage arm 416 and is also configured to secure the user interface 400 to a mounting frame or to a component (e.g., front panel) of an appliance.

The second outer linkage arm 418 of the second hinge assembly 406 is also coupled to a motorized drive assembly 420. In this example, the motorized drive assembly 420 includes an electric drive motor 422 that is mounted to the second outer linkage arm 418. The drive motor 422 may be any type of drive motor described above and may be controlled in any manner described above. A drive shaft of the drive motor 422 may be coupled to one side of a cam plate 424. An opposite side of the cam plate 424 may pass through an aperture in the second outer linkage arm 418 and may be rotatably coupled by a connecting shaft 426 to one end of a drive arm 428 that is arranged between the cam plate and the second inner linkage arm 416. An opposite end of the drive arm 428 can be rotatably coupled to the second inner linkage arm 416, such as by a pin 430 or a similar element. The drive motor 422 may be provided with an electrical connector 432 to provide electrical energy and control commands to the electric drive motor is the same manner described above.

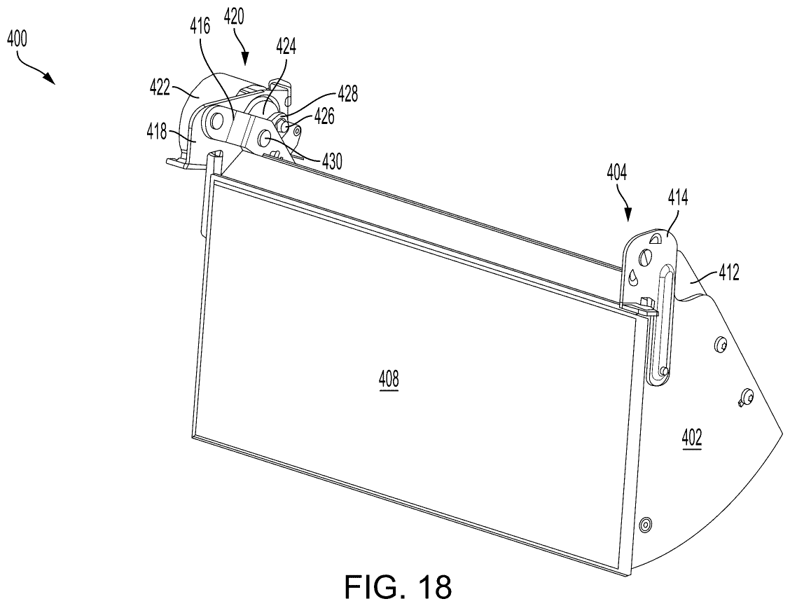

FIG. 18 is an isometric view of a front portion of the user interface 400 illustrated in FIGS. 16-17. The connection of the user interface shell 402 to the hinge assemblies 404, 406 and the coupling of the motorized drive assembly 420 to the second hinge assembly 406 can be observed in FIG. 18. The touchscreen user interface glass 408 that serves as a front face of the user interface 400 in this example is also fully visible. When the user interface 400 is installed to an appliance and placed in a closed position, a front surface of the user interface glass 408 may be flush or substantially flush with a front face of the appliance or a portion (e.g., a front panel assembly) of the appliance.

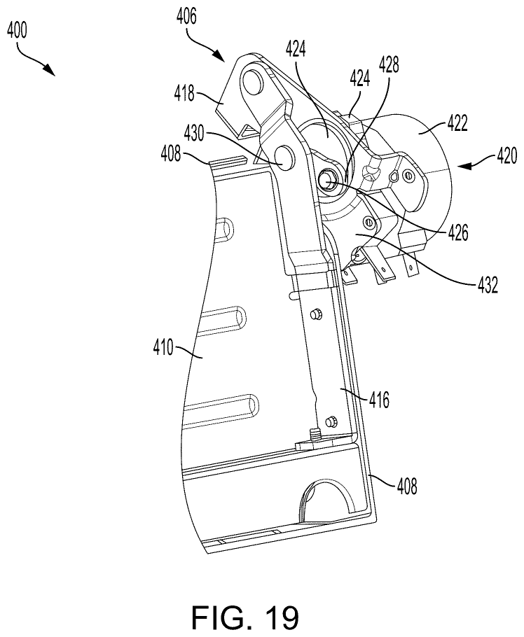

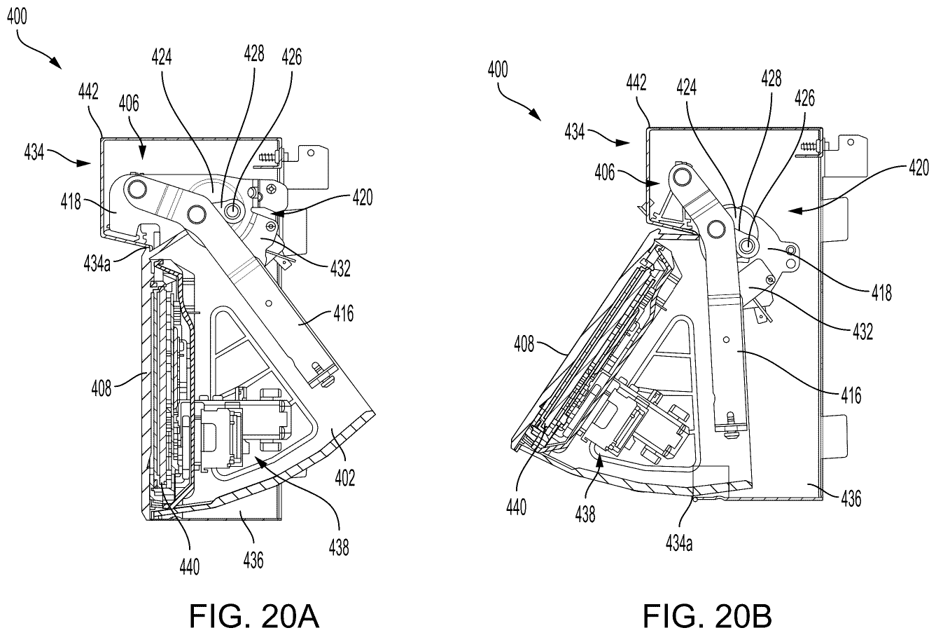

FIG. 19 is an enlarged isometric view of the second hinge assembly 406 and the motorized drive assembly 420 of the user interface 400. The coupling of the drive motor 422 to the drive arm 428 by the cam plate 424 and associated connecting shaft 426, and the corresponding coupling of the drive arm 428 to the second inner linkage arm 416 of the hinge assembly 406 is clearly illustrated in FIG. 19. In operation, a sufficient rotation of the drive shaft of the drive motor 422 in a first direction (clockwise in FIG. 19) will move the user interface shell 402 from an open position to a closed position where the user interface glass 408 is parallel or substantially parallel to a front face of an appliance to which the user interface is installed (see FIG. 20A). Likewise, a sufficient rotation of the drive shaft of the drive motor 422 in a second direction (counterclockwise in FIG. 19) will move the user interface shell 402 from a closed position to an open position where the user shell 402 is articulated relative to the appliance such at least a portion of the touch screen (e.g., the interface glass 408) is translated forward of and also rotated forward relative to a front face of an appliance to which the user interface is installed (see FIG. 20B). In other words, the hinge assemblies 404, 406 cause a movement of the user interface shell 402 by the drive motor 422 to be an articulating movement, as described above with respect to the user interfaces 200, 300.

FIGS. 20A-20B are cross-sectional side views of the user interface 400 taken along line 20-20 of FIG. 16. FIGS. 20A-20B depict the user interface 400 mounted within an appliance 434, such as to a mounting frame or a portion of an appliance cabinet 436. Various electronics 438, such as for example, a touchscreen 440 of the user interface are also visible within an internal volume of the user interface shell 402.

In FIG. 20A, the user interface shell 402 (and the user interface 400) is depicted in a closed position where the user interface glass 408 is parallel or substantially parallel to a front face 434a of the appliance 434 to which the user interface 400 is installed. In FIG. 20B, the user interface shell 402 (and the user interface 400) is depicted in an open position where the user shell 402 is articulated through an opening in the appliance 434 such that at least a portion of the touch screen (e.g., the interface glass 408) is translated forward of and also rotated forward relative to the front face 434a of the appliance 434. As previously described with respect to the user interfaces 200, 300, this articulating movement of the user interface 400 can place the user interface 400 in an operating position where visibility of and access to the user interface 400 is not impeded, such as by a bullnose 442 of the appliance 434. The translational distance and degrees of rotation of the user interface shell 402 when in the open position may be selectable and may be similar to or the same as described above with respect to the user interfaces 200, 300.

Settings and functionality for the articulating user interfaces 200, 300, 400 as well as features present on the user interfaces 200, 300, 400, which may be accessible via the touchscreens 202, 302, 440 of the user interfaces 200, 300, 400 can be embodied as a computer method, computer system, or computer program product. Accordingly, aspects of the settings and functionality for the user interfaces 200, 300, 400 may take the form of an entirely hardware embodiment, an entirely software embodiment (including firmware, resident software, micro-code, and the like), or an embodiment combining software and hardware aspects, all of which may generally be referred to herein as a “circuit,” “module,” or “system.” Furthermore, aspects of the settings and functionality for the user interfaces 200, 300, 400 may take the form of a computer program product embodied in a computer-readable medium (or media) having computer-readable program code/instructions embodied thereon.

Any combination of computer-readable media may be utilized. Computer-readable media can be a computer-readable signal medium and/or a computer-readable storage medium. A computer-readable storage medium may include an electronic, magnetic, optical, electromagnetic, infrared, and/or semiconductor system, apparatus, or device, or any suitable combination of these. More specific examples of a computer-readable storage medium may include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, and/or any suitable combination of these and/or the like. In the context of this disclosure, a computer-readable storage medium may include any suitable non-transitory, tangible medium that can contain or store a program for use by or in connection with an instruction execution system, apparatus, or device.

A computer-readable signal medium may include a propagated data signal with computer-readable program code embodied therein, for example, in baseband or as part of a carrier wave. Such a propagated signal may take any of a variety of forms, including, but not limited to, electro-magnetic, optical, and/or any suitable combination thereof. A computer-readable signal medium may include any computer-readable medium that is not a computer-readable storage medium and that is capable of communicating, propagating, or transporting a program for use by or in connection with an instruction execution system, apparatus, or device.

Program code embodied on a computer-readable medium may be transmitted using any appropriate medium, including but not limited to wireless, wireline, optical fiber cable, RF, and/or the like, and/or any suitable combination of these.

Computer program code for carrying out operations for aspects of the settings and functionality for the articulating user interface may be written in one or any combination of programming languages, including an object-oriented programming language (such as Java, C++), conventional procedural programming languages (such as C), and functional programming languages (such as Haskell). Mobile apps may be developed using any suitable language, including those previously mentioned, as well as Objective-C, Swift, C #, HTML5, and the like. The program code may execute entirely on a user's computer, partly on the user's computer, as a stand-alone software package, partly on the user's computer and partly on a remote computer, or entirely on the remote computer or server. In the latter scenario, the remote computer may be connected to the user's computer through any type of network, including a local area network (LAN) or a wide area network (WAN), and/or the connection may be made to an external computer (for example, through the Internet using an Internet Service Provider).

Additionally or alternatively, these computer program instructions may be stored in a computer-readable medium that can direct processing logic and/or any other suitable device to function in a particular manner, such that the instructions stored in the computer-readable medium produce an article of manufacture including instructions which implement the function/act specified in the flowchart and/or block diagram block(s).

The computer program instructions can also be loaded onto processing logic and/or any other suitable device to cause a series of operational steps to be performed on the device to produce a computer-implemented process such that the executed instructions provide processes for implementing the functions/acts specified in the flowchart and/or block diagram block(s).

The foregoing description of certain examples, including illustrated examples, has been presented only for the purpose of illustration and description and is not intended to be exhaustive or to limit the disclosure to the precise forms disclosed. Numerous modifications, adaptations, and uses thereof will be apparent to those skilled in the art without departing from the scope of the disclosure.

The following definitions apply herein, unless otherwise indicated.

“Comprising,” “including,” and “having” (and conjugations thereof) are used interchangeably to mean including but not necessarily limited to, and are open-ended terms not intended to exclude additional, unrecited elements or method steps.

Terms such as “first,” “second,” and “third” are used to distinguish or identify various members of a group, or the like, and are not intended to show serial or numerical limitation.

“AKA” means “also known as,” and may be used to indicate an alternative or corresponding term for a given element or elements.

“Articulating,” “articulatable,” or “articulated” as used herein refers to a motion or movement of an object or a group of objects that is simultaneously rotational (e.g., pivotal) and translatory/translational in nature.

“Processing logic” describes any suitable device(s) or hardware configured to process data by performing one or more logical and/or arithmetic operations (e.g., executing coded instructions). For example, processing logic may include one or more processors (e.g., central processing units (CPUs) and/or graphics processing units (GPUs)), microprocessors, clusters of processing cores, FPGAs (field-programmable gate arrays), artificial intelligence (AI) accelerators, digital signal processors (DSPs), and/or any other suitable combination of logic hardware.

A “controller” or an “electronic controller” includes processing logic programmed with instructions to carry out a controlling function with respect to a control element. For example, an electronic controller may be configured to receive an input signal, compare the input signal to a selected control value or setpoint value, and determine an output signal to a control element (e.g., a motor or actuator) to provide corrective action based on the comparison. In another example, an electronic controller may be configured to interface between a host device (e.g., a desktop computer, a mainframe, etc.) and a peripheral device (e.g., a memory device, an input/output device, etc.) to control and/or monitor input and output signals to and from the peripheral device.

“Providing,” in the context of a method, may include receiving, obtaining, purchasing, manufacturing, generating, processing, preprocessing, and/or the like, such that the object or material provided is in a state and configuration for other steps to be carried out.

What is claimed is:

1. An articulating user interface for an appliance, comprising:
a user interface shell for housing a user interface;
a mounting frame having an opening;
a first hinge assembly and a second hinge assembly arranged along opposite sides of the opening and configured to rotatably couple the user interface shell to a respective hinge case; and
wherein the user interface shell is configured to articulate from a position where a front panel of the user interface shell is substantially parallel with a front of the appliance to a position where at least the front panel of the user interface shell extends outwardly from the appliance by the first hinge assembly and the second hinge assembly causing the user interface shell to extend outwardly from the appliance.

2. The articulating user interface of claim 1, wherein:
the opening in the mounting frame is bounded by an upper frame member and first and second side frame members of the mounting frame, the first and second side members arranged at opposite ends of the upper frame member and extending transversely and rearwardly therefrom;
each hinge assembly includes an inner linkage arm rotatably coupled between an inner face of the hinge case of the respective hinge assembly and the mounting frame and an outer linkage arm rotatably coupled between an outer face of the hinge case of the respective hinge assembly and the mounting frame;
a drive motor is mounted to one of the side frame members of the mounting frame with an output shaft of the drive motor coupled to one of the hinge cases; and
wherein the user interface shell is articulatable, by a rotation of the drive motor output shaft, through the opening in the mounting frame and between the position where the front panel of the user interface shell is substantially parallel with the front of the appliance to the position where at least the front panel of the user interface shell extends outwardly from the appliance.

3. The articulating user interface of claim 2, wherein:
first ends of the inner linkage arm and the outer linkage arm of the first hinge assembly are rotatably coupled to the hinge case of the first hinge assembly at different locations, and second ends of the inner linkage arm and the outer linkage arm of the first hinge assembly are rotatably coupled to a first attachment bracket on the upper frame member at different locations;
first ends of the inner linkage arm and the outer linkage arm of the second hinge assembly are rotatably coupled to the hinge case of the second hinge assembly at different locations, and second ends of the inner linkage arm and the outer linkage arm of the second hinge assembly are rotatably coupled to a second attachment bracket on the upper frame member at different locations; and
wherein, each of the first hinge assembly and the second hinge assembly is configured as a four-pivot point hinge assembly via which movement of the user interface shell is directable along a simultaneously rotational and translational path.

4. The articulating user interface of claim 2, wherein:
the drive motor is mounted to an outer face of the first side frame member of the mounting frame such that the drive motor lies outside an area defined by the opening in the mounting frame;
a drive shaft of the drive motor extends through an aperture in the first side frame member and toward the first hinge assembly, and is coupled to a rotatable cam plate near a first end thereof; and
a connecting shaft extends from near a second end of the rotatable cam plate through a slot in the hinge case of the first hinge assembly, such that the drive motor output shaft is coupled to the hinge case of the first hinge assembly and the hinge case of the first hinge assembly is rotatable by rotation of the drive shaft.

5. The articulating user interface of claim 2, wherein:
the drive motor is mounted to the upper frame member of the mounting frame by a motor mount such that the drive motor overlies an area defined by the opening in the mounting frame;
a drive shaft of the drive motor extends through an aperture in the motor mount and toward the first hinge assembly, and is coupled to a rotatable cam plate near a first end thereof; and
a connecting shaft extends from near a second end of the rotatable cam plate through a slot in the hinge case of the first hinge assembly, such that the drive motor output shaft is coupled to the hinge case of the first hinge assembly and the hinge case of the first hinge assembly is rotatable by rotation of the drive shaft.

6. The articulating user interface of claim 1, further comprising:
at least one sensor to detect a position of the user interface shell; and
a controller communicatively coupled to the at least one sensor and configured to receive and interpret position signals transmitted by the at least one sensor to generate operating commands for a drive motor coupled to the user interface shell using the signals.

7. The articulating user interface of claim 1, wherein;
the user interface shell position where the front panel of the user interface shell is substantially parallel with the front of the appliance is a closed position of the user interface;
the user interface shell position where at least the front panel of the user interface shell extends outwardly from the appliance is an open position of the user interface; and
an angle at which at least the front panel of the user interface shell extends outwardly from the appliance in the open position is selectable between 1° to 45°.

8. A household appliance, comprising:
a cabinet including a front face and a user interface opening in the front face;
an articulating user interface mounted in the cabinet and aligned with the user interface opening therein, the articulating user interface comprising:
a user interface shell for housing a user interface,
a mounting frame having an opening, and
a first hinge assembly and a second hinge assembly arranged along opposite sides of the opening and configured to rotatably couple the user interface shell to a respective hinge case; and
wherein the user interface shell is configured to articulate from a position where a front panel of the user interface shell is substantially parallel with a front of the appliance to a position where at least the front panel of the user interface shell extends outwardly from the appliance by the first hinge assembly and the second hinge assembly causing the user interface shell to extend outwardly from the appliance.

9. The household appliance of claim 8, wherein:
first ends of an inner linkage arm and an outer linkage arm of the first hinge assembly are rotatably coupled to the hinge case of the first hinge assembly at different locations, and second ends of the inner linkage arm and the outer linkage arm of the first hinge assembly are rotatably coupled to a first attachment bracket on an upper frame member of the mounting frame at different locations;
first ends of an inner linkage arm and an outer linkage arm of the second hinge assembly are rotatably coupled to the hinge case of the second hinge assembly at different locations, and second ends of the inner linkage arm and the outer linkage arm of the second hinge assembly are rotatably coupled to a second attachment bracket on the upper frame member of the mounting frame at different locations; and
wherein, each of the first hinge assembly and the second hinge assembly is configured as a four-pivot point hinge assembly via which movement of the user interface shell is directable along a simultaneously rotational and translational path.

10. The household appliance of claim 8, wherein:
a drive motor is mounted to an outer face of a first side frame member of the mounting frame such that the drive motor lies outside an area defined by the opening in the mounting frame;
a drive shaft of the drive motor extends through an aperture in the first side frame member and toward the first hinge assembly, and is coupled to a rotatable cam plate near a first end thereof; and
a connecting shaft extends from near a second end of the rotatable cam plate through a slot in the hinge case of the first hinge assembly, such that the drive shaft of the drive motor is coupled to the hinge case of the first hinge assembly and the hinge case of the first hinge assembly is rotatable by rotation of the drive shaft.

11. The household appliance of claim 8, wherein:
a drive motor is mounted to an upper frame member of the mounting frame by a motor mount such that the drive motor overlies an area defined by the opening in the mounting frame;
a drive shaft of the drive motor extends through an aperture in the motor mount and toward the first hinge assembly, and is coupled to a rotatable cam plate near a first end thereof; and
a connecting shaft extends from near a second end of the rotatable cam plate through a slot in the hinge case of the first hinge assembly, such that the drive shaft of the drive motor is coupled to the hinge case of the first hinge assembly and the hinge case of the first hinge assembly is rotatable by rotation of the drive shaft.

12. The household appliance of claim 8, wherein:
the user interface shell position where the front panel of the user interface shell is substantially parallel with the front of the appliance is a closed position of the user interface;
the user interface shell position where at least the front panel of the user interface shell extends outwardly from the appliance is an open position of the user interface; and
an angle at which at least the front panel of the user interface shell extends outwardly from the appliance in the open position is selectable between 1° to 45°.

13. The household appliance of claim 8, further comprising:
at least one sensor to detect a position of the user interface shell; and
a controller communicatively coupled to the at least one sensor and configured to receive and interpret position signals transmitted by the at least one sensor to generate operating commands for a drive motor coupled to the user interface shell using the signals.

14. A method comprising:
receiving a command to articulate a user interface of an appliance;
in response to receiving the command, causing a first hinge assembly and a second hinge assembly coupled to respective hinge cases and arranged along opposite sides of an opening in a mounting frame to rotate; and
in response to the first hinge assembly and the second hinge assembly rotating, articulating a user interface shell coupled to the first hinge assembly and the second hinge assembly from a position where a front panel of the user interface shell is substantially parallel with a front of the appliance to a position where at least the front panel of the user interface shell extends outwardly from the appliance.

15. The method of claim 14, wherein an angle at which at least the front panel of the user interface shell extends outwardly from the appliance is selectable between 1° to 45°.

16. The method of claim 14, further comprising:
mounting a drive motor to an outer face of a first side frame member of the mounting frame such that the drive motor lies outside an area defined by the opening in the mounting frame;
directing a drive shaft of the drive motor through an aperture in the first side frame member and toward the first hinge assembly and coupling the drive shaft to a rotatable cam plate near a first end thereof;
directing a connecting shaft that extends from near a second end of the rotatable cam plate through a slot in the hinge case of the first hinge assembly such that the drive shaft of the drive motor is coupled to the hinge case of the first hinge assembly; and
selectively articulating the user interface shell by operating the drive motor to rotate the hinge case of the first hinge assembly.

17. The method of claim 14, wherein:
mounting a drive motor to an upper frame member of the mounting frame by a motor mount such that the drive motor overlies an area defined by the opening in the mounting frame;
directing a drive shaft of the drive motor through an aperture in the motor mount and toward the first hinge assembly and coupling the drive shaft to a rotatable cam plate near a first end thereof;
directing a connecting shaft that extends from near a second end of the rotatable cam plate through a slot in the hinge case of the first hinge assembly such that the drive shaft of the drive motor is coupled to the hinge case of the first hinge assembly; and
selectively articulating the user interface shell by operating the drive motor to rotate the hinge case of the first hinge assembly.

18. The method of claim 14, further comprising
arranging at least one sensor to detect the position of the user interface shell of the user interface; and
transmitting position signals generated by the at least one sensor to a controller communicatively coupled to the at least one sensor and using the signals, by the controller, to generate and transmit operating commands to a drive motor coupled to the user interface shell.

19. The method of claim 14, wherein an articulating movement of the user interface shell is initiated through a touchscreen implemented in the front panel of the user interface shell.

20. The method of claim 14, wherein an articulating movement of the user interface shell is initiated by a signal transmitted by a sensor associated with the user interface in response to detecting or not detecting a user within a predetermined proximity to the front panel of the user interface shell.
